(19) United States
(12) Patent Application Publication
(10) Pub. No.: US 2026/0352192 A1
(43) Pub. Date: Nov. 5, 2026

(54) FREQUENCY ADJUSTMENT DEVICE, FREQUENCY ADJUSTMENT SYSTEM AND FREQUENCY ADJUSTMENT METHOD

(71) Applicant: Realtek Semiconductor Corporation, Hsinchu (TW)

(72) Inventors: Ching-Feng HUANG, Hsinchu (TW); Han-Chieh HSIEH, Hsinchu (TW)

(21) Appl. No.: 19/555,856

(22) Filed: Mar. 3, 2026

(30) Foreign Application Priority Data
Mar. 10, 2025 (TW) 114108774

(51) Int. Cl. H03K 5/00; H03K 5/125

(52) U.S. Cl. CPC H03K 5/00006; H03K 5/125

(57) ABSTRACT

A frequency adjustment device connected to an electronic device and comprising one or more voltage detection circuit(s), a frequency control circuit and a clock providing circuit is provided. The voltage detection circuit(s) detects a supply voltage of the electronic device and compares the supply voltage with multiple voltage thresholds to output a detection signal comprising multiple bits respectively related to magnitudes of the supply voltage and the voltage thresholds. The frequency control circuit receives the detection signal and generates a clock selection signal based on the detection signal. The clock providing circuit comprises multiple clock sources and a clock selecting circuit. The clock sources generate multiple clock signals with different frequencies. The clock selecting circuit receives the clock selection signal, selects one of the clock signals as a system clock signal according to the clock selection signal, and outputs the system clock signal to the electronic device.

### RELATED APPLICATIONS

This application claims priority to Taiwan Application Serial Number 114108774, filed on Mar. 10, 2025, which is herein incorporated by reference in its entirety.

### BACKGROUND

### Technical Field

The present disclosure relates to frequency adjustment technology. More particularly, the present disclosure relates to a frequency adjustment device, a frequency adjustment system and a frequency adjustment method capable of adjusting system frequency in real time according to supply voltage.

### Description of Related Art

The processor of a system-on-a-chip (SoC) may cause a momentary voltage drop in the supply voltage due to executing heavy-loaded programs. Once the supply voltage drops below a crash voltage, the circuit will fail. Therefore, in some technologies, when a voltage drop in the supply voltage is detected, the frequency of the clock signal will be rapidly reduced to reduce the power consumption of the circuit, so that the supply voltage can be restored to its original level.

Currently, a common frequency control method is to use a circuit (e.g., a frequency division circuit) to perform integrated clock gating (ICG), so as to mask the system clock. However, when using ICG for frequency masking, the period between clocks (i.e., critical path timing) can be effectively widen only when the frequency masking is performed at integer multiples. However, integer-multiple masking will reduce the system frequency too much (e.g., 2× masking will remove half of the clock signal), which will lead to poor system performance and stability. Therefore, how to effectively adjust the system frequency without affecting the system performance and stability is one of the topics in this field.

### SUMMARY

A frequency adjustment device is provided in the present disclosure. The frequency adjustment device is connected to an electronic device and comprises one or more voltage detection circuits, a frequency control circuit and a clock providing circuit. The one or more voltage detection circuits are configured to detect a supply voltage of the electronic device and compare the supply voltage with a plurality of voltage thresholds to output a detection signal. The detection signal is a digital signal comprising a plurality of bits respectively related to magnitudes of the supply voltage and the plurality of voltage thresholds. The frequency control circuit is coupled to the one or more voltage detection circuits, and is configured to receive the detection signal and generate a clock selection signal based on the detection signal. The clock providing circuit is coupled to the frequency control circuit and comprises a plurality of clock sources and a clock selecting circuit. The plurality of clock sources are configured to generate a plurality of clock signals, wherein frequencies of the plurality of clock signals are different from each other. The clock selecting circuit is coupled to the plurality of clock sources, and is configured to receive the clock selection signal, select one of the plurality of clock signals as a system clock signal according to the clock selection signal, and output the system clock signal to the electronic device.

A frequency adjustment system is provided in the present disclosure. The frequency adjustment system comprises one or more electronic devices, one or more voltage detection circuits, a frequency control circuit and a clock providing circuit. The one or more electronic devices are configured to operate based on a system clock signal and a supple voltage. The one or more voltage detection circuits are coupled to the one or more electronic devices respectively, and are configured to detect the supply voltage and compare the supply voltage with a plurality of voltage thresholds, so as to output a detection signal. The detection signal is a digital signal comprising a plurality of bits respectively related to magnitudes of the supply voltage and the plurality of voltage thresholds. The frequency control circuit is coupled to the one or more voltage detection circuits, and is configured to receive the detection signal and generate a clock selection signal based on the detection signal. The clock providing circuit is coupled to the frequency control circuit and the one or more electronic devices, and comprises a plurality of clock sources and a clock selecting circuit. The plurality of clock sources are configured to generate a plurality of clock signals, wherein frequencies of the plurality of clock signals are different from each other. The clock selecting circuit is coupled to the plurality of clock sources, and is configured to receive the clock selection signal, select one of the plurality of clock signals as a system clock signal according to the clock selection signal, and output the system clock signal to the one or more electronic devices.

A frequency adjustment method is provided in the present disclosure. The frequency adjustment method is suitable for a frequency adjustment system and comprises: detecting, by one or more voltage detection circuits of the frequency adjustment system, a supply voltage of the frequency adjustment system; comparing, by the one or more voltage detection circuits, the supply voltage with a plurality of voltage thresholds, so as to output a detection signal, wherein the detection signal is a digital signal comprising a plurality of bits respectively related to magnitudes of the supply voltage and the plurality of voltage thresholds; receiving, by a frequency control circuit of the frequency adjustment system, the detection signal; generating, by the frequency control circuit, a clock selection signal, based on the detection signal; receiving, by a clock providing circuit of the frequency adjustment system, the clock selection signal; selecting, by the clock providing circuit, one of a plurality of clock signals generated by a plurality of clock sources as a system clock signal according to the clock selection signal, wherein frequencies of the plurality of clock signals are different from each other; and outputting, by the clock providing circuit, the system clock signal to one or more electronic devices of the frequency adjustment system.

With the frequency adjustment device, frequency adjustment system and frequency adjustment method provided in the present disclosure, the system frequency can be adjusted in real time by non-integer multiples. In addition to avoiding system instability caused by a sudden drop in system frequency, the flexibility of system frequency adjustment can also be improved.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows.

FIG. 1 is a functional block diagram of a frequency adjustment device in accordance with some embodiments of the present disclosure.

FIG. 2 is a timing diagram of frequencies of a supply voltage, a detection signal and a system clock signal in accordance with some embodiments of the present disclosure.

FIG. 3 is a functional block diagram of a frequency adjustment system in accordance with some embodiments of the present disclosure.

FIG. 4 is a flowchart of a frequency adjustment method in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

As used in the present disclosure, the singular forms “a”, “one” and “the” are also intended to include plural forms, unless the context clearly indicates otherwise. It will be further understood that when used in this specification, the terms “comprises (comprising)”, “includes (including)” and/or “haves (having)” designate the existence of stated features, regions, integers, steps, operations, elements and/or components, but the existence or addition of one or more other features, regions, integers, steps, operations, elements, components, and/or groups thereof are not excluded.

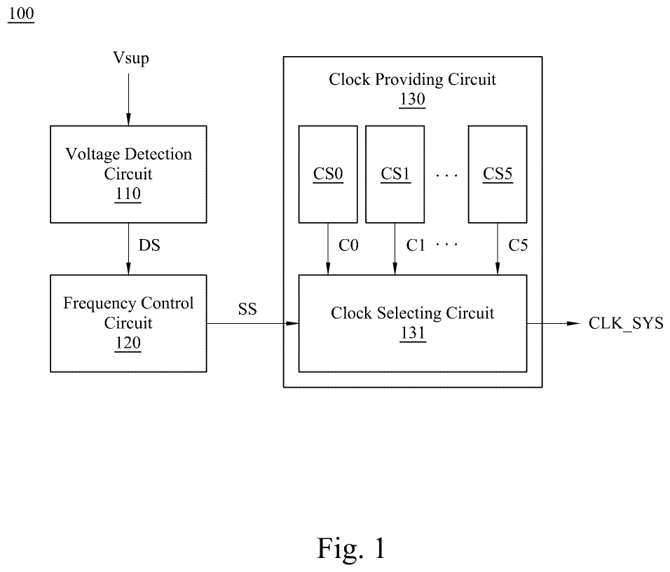

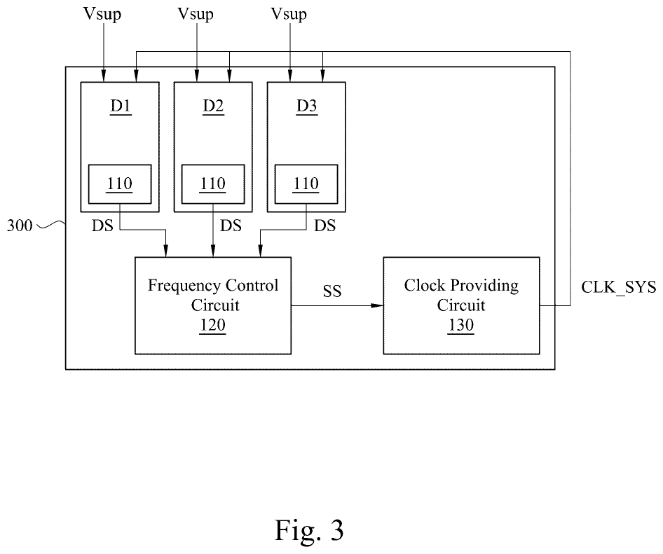

FIG. 1 is a functional block diagram of a frequency adjustment device 100 in accordance with some embodiments of the present disclosure. The frequency adjustment device 100 is configured to detect a supply voltage Vsup provided by a circuit system (not shown in FIG. 1, but will be described in FIG. 3) and generate a corresponding system clock signal CLK_SYS to the circuit system, so as to adjust the system frequency of the circuit system. In some embodiments, the frequency adjustment device 100 comprises a voltage detection circuit 110, a frequency control circuit 120 and a clock providing circuit 130.

The voltage detection circuit 110 is coupled to the frequency control circuit 120 and electronic devices of the circuit system (not shown in FIG. 1, but will be described in FIG. 3), and is configured to detect the supply voltage Vsup provided to the electronic devices, compare the supply voltage Vsup with a plurality of voltage thresholds, and output a detection signal DS according to the result of comparison. The method for generating the detection signal DS will be described in detail in subsequent paragraphs.

The frequency control circuit 120 is coupled to the voltage detection circuit 110 and the clock providing circuit 130, and is configured to receive the detection signal DS and generate a clock selection signal SS based on the detection signal DS.

The clock providing circuit 130 is coupled to the frequency control circuit 120, and comprises clock sources CS0-CS5 and a clock selecting circuit 131. The clock sources CS0-CS5 are respectively coupled to the clock selecting circuit 131, and are configured to generate clock signals C0-C5 to the clock selecting circuit 131, respectively, wherein the frequencies of the clock signals C0-C5 are different from each other. The clock selecting circuit 131 is configured to receive the clock signals C0-C5 from the clock sources CS0-CS5, receive the clock selection signal SS from the frequency control circuit 120, select one of the clock signals C0-C5 as the system clock signal CLK_SYS according to the clock selection signal SS, and then output the system clock signal CLK_SYS to the electronic devices of the circuit system.

It should be noted that the numbers of the voltage detection circuit 110, the clock sources CS0-CS5 and the clock signals C0-C5 in FIG. 1 are only examples, and are not intended to limit the present disclosure. Other numbers of the voltage detection circuits, the clock sources and the clock signals are within the scope of the present disclosure. In some embodiments not shown, the frequency adjustment device 100 may comprise a plurality of voltage detection circuits 110. These voltage detection circuits 110 are configured to jointly detect the supply voltage Vsup of the electronic devices and jointly output the detection signal DS.

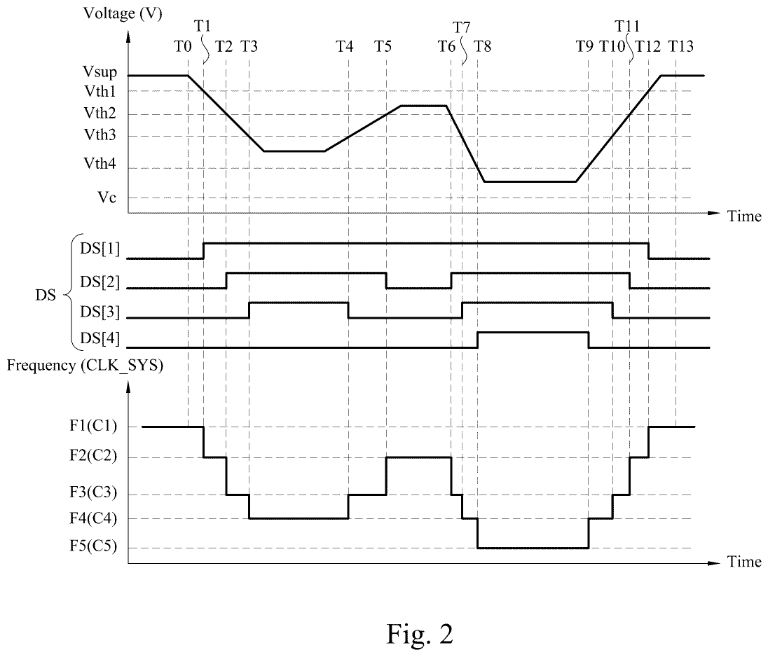

In some embodiments, the detection signal DS output by the voltage detection circuit 110 is a digital signal comprising a plurality of bits, and these bits are respectively related to the magnitude relationship between the supply voltage Vsup and a plurality of voltage thresholds, and determine the clock signal selected by the clock selecting circuit 131 as the system clock signal CLK_SYS. Please refer to FIG. 2. FIG. 2 is a timing diagram of the frequencies of the supply voltage Vsup, the detection signal DS and the system clock signal CLK_SYS in accordance with some embodiments of the present disclosure.

In the embodiment of FIG. 2, the detection signal DS comprises bits DS[1]-DS[4], wherein the bit DS[1] is related to the magnitude relationship between the supply voltage Vsup and a voltage threshold Vth1; the bit DS[2] is related to the magnitude relationship between the supply voltage Vsup and a voltage threshold Vth2; the bit DS[3] is related to the magnitude relationship between the supply voltage Vsup and a voltage threshold Vth3; and the bit DS[4] is related to the magnitude relationship between the supply voltage Vsup and a voltage threshold Vth4. In some embodiments, the voltage thresholds Vth1-Vth4 form a decreasing sequence (i.e., the voltage threshold Vth1 is greater than the voltage threshold Vth2, the voltage threshold Vth2 is greater than the voltage threshold Vth3, and the voltage threshold Vth3 is greater than the voltage threshold Vth4).

In some embodiments, for each of the bits DS[1]-DS[4], when the supply voltage Vsup is lower than its corresponding voltage threshold, the corresponding bit is at a first logic state (e.g., logic 1, but the present disclosure is not limited thereto). On the contrary, when the supply voltage Vsup is greater than or equal to its corresponding voltage threshold, the corresponding bit is at a second logic state (e.g., logic 0, but the present disclosure is not limited thereto) different from the first logic state.

Furthermore, in some embodiments, the logic states of the bits DS[1]-DS[4] determine the sequence of the clock selection signal SS, and further determine the clock signal selected by the clock selecting circuit 131 as the system clock signal CLK_SYS. Specifically, when N bits among the bits DS[1]-DS[4] are at the first logic state, the clock selecting circuit 131 will select the clock signal with the (N+1)^{th} largest frequency among all clock signals as the system clock signal CLK_SYS, wherein N is a non-negative integer (i.e., an integer greater than or equal to 0).

Taking the embodiment of FIG. 2 as an example, first, at time T0, since the supply voltage Vsup is greater than the voltage thresholds Vth1-Vth4, the bits DS[1]-DS[4] of the detection signal DS are all at logic 0. Since the number of bits at the first logic state (i.e., logic 1) is 0, the clock selecting circuit 131 selects the clock signal C1 with the highest frequency F1 as the system clock signal CLK_SYS, according to the clock selection signal SS corresponding to the detection signal DS.

Next, at time T1, T2 and T3, the supply voltage Vsup drops below the voltage thresholds Vth1, Vth2 and Vth3, respectively, so that the bits DS[1], DS[2] and DS[3] are switched to logic 1 in sequence. Since the number of bits at the first logic state (i.e., logic 1) will change to 1, 2 and 3 at times T1, T2 and T3, respectively, the clock selecting circuit 131 will sequentially select the clock signals C2, C3 and C4 with the second highest, third highest and fourth highest frequencies F2, F3 and F4 as the system clock signal CLK_SYS at times T1, T2 and T3, according to the clock selection signals SS corresponding to these detection signals DS.

Next, at time T4 and T5, the supply voltage Vsup rises to above the voltage thresholds Vth3 and Vth2, respectively, so that the bits DS[3] and DS[2] are switched back to logic 0 in sequence, while the bit DS[1] remains at logic 1. Since the number of bits at the first logic state (i.e., logic 1) will change to 2 and 1 at time T4 and T5, respectively, the clock selecting circuit 131 will sequentially select the clock signals C3 and C2 with the third highest and second highest frequencies F3 and F2 as the system clock signal CLK_SYS at time T4 and T5, according to the clock selection signals SS corresponding to these detection signals DS.

Next, at time T6, T7 and T8, the supply voltage Vsup drops again and drops below the voltage thresholds Vth2, Vth3 and Vth4, respectively, so that the bits DS[2], DS[3] and DS[4] are switched to logic 1 in sequence, while the bit DS[1] still remains at logic 1. Since the number of bits at the first logic state (i.e., logic 1) will change to 2, 3 and 4 at times T6, T7 and T8, respectively, the clock selecting circuit 131 will sequentially select the clock signals C3, C4 and C5 with the third highest, fourth highest and fifth highest frequencies F3, F4 and F5 as the system clock signal CLK_SYS at times T6, T7 and T8, according to the clock selection signals SS corresponding to these detection signals DS.

Finally, at time T9, T10, T11 and T12, the supply voltage Vsup rises above the voltage thresholds Vth4, Vth3, Vth2 and Vth1, respectively, so that the bits DS[4], DS[3], DS[2] and DS[1] are switched back to logic 0 in sequence. Since the number of bits at the first logic state (i.e., logic 1) will change to 3, 2, 1 and 0 at times T9, T10, T11 and T12, respectively, the clock selecting circuit 131 will sequentially select the clock signals C4, C3, C2 and C1 with the fourth highest, third highest, second highest and highest frequencies F4, F3, F2 and F1 as the system clock signal CLK_SYS at times T9, T10, T11 and T12, according to the clock selection signals SS corresponding to these detection signals DS, and maintain stability at the clock signal C1 in the final time T13.

Through the above operations, the frequency adjustment device 100 can adjust the frequency of the system clock signal CLK_SYS in real time when the supply voltage Vsup drops, so as to gradually restore the supply voltage Vsup to its original level and prevent the supply voltage Vsup from dropping below the crash voltage Vc.

In some embodiments, the clock selection signal SS generated by the frequency control circuit 120 is also a digital signal comprising a plurality of bits, and the number of bits of the clock selection signal SS is greater than the number of bits of the detection signal DS. Taking the embodiment of FIG. 2 as an example, when the frequency control circuit 120 receives a detection signal DS with a bit sequence of “4′b0000” (i.e., four bits are all 0), since the number of logic 1 is 0, it means that the supply voltage Vsup is lower than 0 voltage thresholds, so the frequency control circuit 120 will generate a clock selection signal SS with a bit sequence of “5′b0_0001” (i.e., five bits are 0, 0, 0, 0, 1 in sequence), which represents the selection of the clock signal with the highest frequency; when the frequency control circuit 120 receives a detection signal DS with a bit sequence of “4′b0001” (i.e., four bits are 0, 0, 0, 1 in sequence), since the number of logic 1 is 1, it means that the supply voltage Vsup is lower than 1 voltage threshold, so the frequency control circuit 120 will generate a clock selection signal SS with a bit sequence of “5′b0_0010” (i.e., five bits are 0, 0, 0, 1, 0 in sequence), which represents the selection of the clock signal with the second highest frequency. Similarly, the detection signals DS with bit sequences of “4′b0011”, “4′b0111” and “4′b1111” are corresponding to the clock selection signals SS with bit sequences of “5′b0_0100”, “5′b0_1000” and “5′b1_0000”, respectively, which represent the selections of the clock signals with the third highest, fourth highest and fifth highest frequency, respectively.

In some other embodiments, the clock selection signal SS generated by the frequency control circuit 120 is also a digital signal comprising a plurality of bits, and the number of bits of the clock selection signal SS is less than the number of bits of the detection signal DS. For example, when the frequency control circuit 120 receives a detection signal DS with a bit sequence of “4′b0000”, since the number of logic 1 is 0, it means that the supply voltage Vsup is lower than 0 voltage thresholds, so the frequency control circuit 120 will generate a clock selection signal SS with a bit sequence of “3′b000” (i.e., three bits are all 0), which represents the selection of the clock signal with the highest frequency; when the frequency control circuit 120 receives a detection signal DS with a bit sequence of “4′b0001”, since the number of logic 1 is 1, it means that the supply voltage Vsup is lower than 1 voltage threshold, so the frequency control circuit 120 will generate a clock selection signal SS with a bit sequence of “3′b001” (i.e., three bits are 0, 0, 1 in sequence), which represents the selection of the clock signal with the second highest frequency. Similarly, the detection signals DS with bit sequences of “4′b0011”, “4′b0111” and “4′b1111” are corresponding to the clock selection signals SS with bit sequences of “3′b010”, “3′b011” and “3′b100”, respectively, which represent the selections of the clock signals with the third highest, fourth highest and fifth highest frequency, respectively.

FIG. 3 is a functional block diagram of a frequency adjustment system 300 in accordance with some embodiments of the present disclosure. In some embodiments, the frequency adjustment system 300 comprises electronic devices D1-D3, a plurality of voltage detection circuits 110, a frequency control circuit 120 and a clock providing circuit 130.

The electronic devices D1-D3 are configured to operate with the same system clock signal CLK_SYS and the same supply voltage Vsup, and are respectively connected to at least one voltage detection circuit 110. Each of the voltage detection circuits 110 is configured to output the detection signal DS to the frequency control circuit 120. The frequency control circuit 120 then generates the clock selection signal SS to the clock providing circuit 130 according to the detection signal DS. The clock providing circuit 130 then transmits the corresponding system clock signals CLK_SYS back to the electronic devices D1-D3 of the frequency adjustment system 300 according to the clock selection signal SS. The detailed manner in which the clock providing circuit 130 selects the corresponding system clock signals CLK_SYS will not be repeated here.

It should be noted that the numbers of electronic devices and voltage detection circuits in FIG. 3 are only examples, and are not intended to limit the present disclosure. Other numbers of electronic devices and voltage detection circuits are within the scope of the present disclosure.

In addition, in some embodiments not shown, the clock providing circuit 130 further comprises a glitch detection circuit. The glitch detection circuit is configured to prevent a glitch from being generated in the system clock signal CLK_SYS.

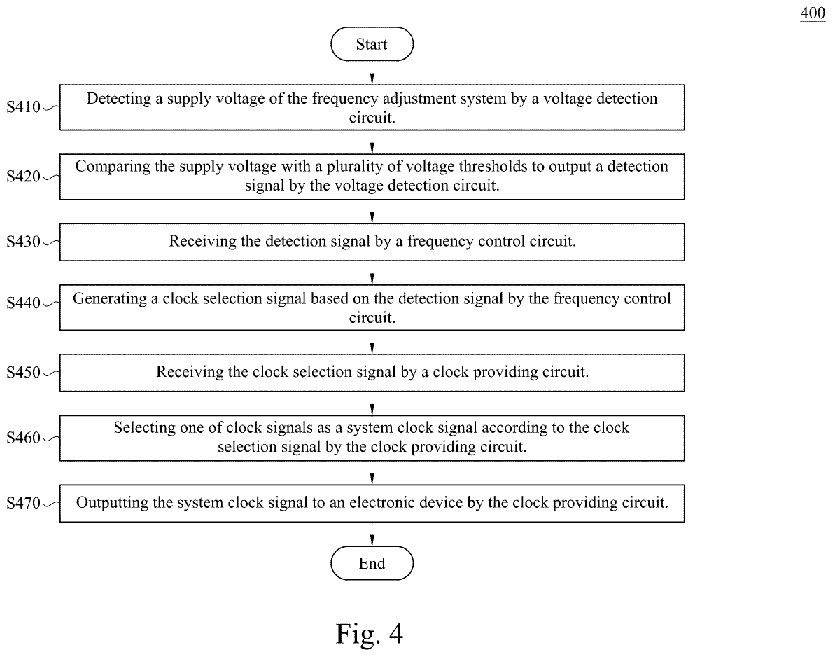

FIG. 4 is a flowchart of a frequency adjustment method 400 in accordance with some embodiments of the present disclosure. The frequency adjustment method 400 is suitable for a frequency adjustment system (e.g., the frequency adjustment system 300). In some embodiments, the frequency adjustment method 400 comprises steps S410, S420, S430, S440, S450, S460 and S470.

The frequency adjustment method 400 starts from step S410. In step S410, a voltage detection circuit (e.g., the voltage detection circuit 110) of the frequency adjustment system detects a supply voltage (e.g., the supply voltage Vsup) of the frequency adjustment system. Next, step S420 will be performed.

In step S420, the voltage detection circuit compares the supply voltage with a plurality of voltage thresholds (e.g., the voltage thresholds Vth1-Vth4), so as to output a detection signal (e.g., the detection signal DS). Next, step S430 will be performed.

In step S430, a frequency control circuit (e.g., the frequency control circuit 120) of the frequency adjustment system receives a detection signal. Next, step S440 will be performed.

In step S440, the frequency control circuit generates a clock selection signal (e.g., the clock selection signal SS) based on the detection signal. Next, step S450 will be performed.

In step S450, a clock providing circuit (e.g., the clock providing circuit 130) of the frequency adjustment system receives the clock selection signal. Next, step S460 will be performed.

In step S460, the clock providing circuit selects one of the clock signals (e.g., one of the clock signals C0-C5) as a system clock signal (e.g., the system clock signal CLK_SYS) according to the clock selection signal. Next, step S470 will be performed.

In step S470, the clock providing circuit outputs the system clock signal to electronic devices.

It should be noted that the number and order of steps in the frequency adjustment method 400 of the present disclosure are only examples, and are not intended to limit the present disclosure. Other numbers and orders of steps are within the scope of the present disclosure.

With the frequency adjustment device 100, frequency adjustment system 300 and frequency adjustment method 400 provided in the present disclosure, the system frequency can be adjusted in real time by non-integer multiples without using integrated clock gating (ICG), and in some embodiments, it is possible to detect whether there is a glitch in the system clock signal, thereby improving the flexibility and stability of the system.

The above are preferred embodiments of the present disclosure. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

What is claimed is:

1. A frequency adjustment device, connected to an electronic device and comprising:
one or more voltage detection circuits, configured to detect a supply voltage of the electronic device and compare the supply voltage with a plurality of voltage thresholds to output a detection signal, wherein the detection signal is a digital signal comprising a plurality of bits respectively related to magnitudes of the supply voltage and the plurality of voltage thresholds;
a frequency control circuit, coupled to the one or more voltage detection circuits, and configured to receive the detection signal and generate a clock selection signal based on the detection signal; and
a clock providing circuit, coupled to the frequency control circuit and comprising:
a plurality of clock sources, configured to generate a plurality of clock signals, wherein frequencies of the plurality of clock signals are different from each other; and
a clock selecting circuit, coupled to the plurality of clock sources and configured to receive the clock selection signal, select one of the plurality of clock signals as a system clock signal according to the clock selection signal, and output the system clock signal to the electronic device.

2. The frequency adjustment device of claim 1, wherein when the supply voltage is lower than one of the plurality of voltage thresholds, a corresponding one of the plurality of bits of the detection signal is at a first logic state,
wherein when the supply voltage is higher than or equal to the one of the plurality of voltage thresholds, the corresponding one of the plurality of bits of the detection signal is at a second logic state, and
wherein the first logic state is different from the second logic state.

3. The frequency adjustment device of claim 2, wherein the plurality of voltage thresholds form a decreasing sequence, and the plurality of bits of the detection signal are sequentially corresponding to the plurality of voltage thresholds of the decreasing sequence.

4. The frequency adjustment device of claim 2, wherein when N of the plurality of bits of the detection signal are at the first logic state, the frequency of the system clock signal is the (N+1)^{th} largest of the frequencies of the plurality of clock signals, wherein N is a non-negative integer.

5. The frequency adjustment device of claim 1, wherein the clock selection signal is a digital signal comprising a plurality of bits, and the number of the plurality of bits of the detection signal is different from the number of the plurality of bits of the clock selection signal.

6. The frequency adjustment device of claim 1, wherein the clock providing circuit further comprises a glitch detection circuit configured to prevent a glitch from being generated in the system clock signal.

7. A frequency adjustment system, comprising:
one or more electronic devices, configured to operate with a system clock signal and a supple voltage;
one or more voltage detection circuits, coupled to the one or more electronic devices respectively and configured to detect the supply voltage and compare the supply voltage with a plurality of voltage thresholds to output a detection signal, wherein the detection signal is a digital signal comprising a plurality of bits respectively related to magnitudes of the supply voltage and the plurality of voltage thresholds;
a frequency control circuit, coupled to the one or more voltage detection circuits, and configured to receive the detection signal and generate a clock selection signal based on the detection signal; and
a clock providing circuit, coupled to the frequency control circuit and the one or more electronic devices, and comprising:
a plurality of clock sources, configured to generate a plurality of clock signals, wherein frequencies of the plurality of clock signals are different from each other; and
a clock selecting circuit, coupled to the plurality of clock sources and configured to receive the clock selection signal, select one of the plurality of clock signals as a system clock signal according to the clock selection signal, and output the system clock signal to the one or more electronic devices.

8. The frequency adjustment system of claim 7, wherein when the supply voltage is lower than one of the plurality of voltage thresholds, a corresponding one of the plurality of bits of the detection signal is at a first logic state,
wherein when the supply voltage is higher than or equal to the one of the plurality of voltage thresholds, the corresponding one of the plurality of bits of the detection signal is at a second logic state, and
wherein the first logic state is different from the second logic state.

9. The frequency adjustment system of claim 8, wherein the plurality of voltage thresholds form a decreasing sequence, and the plurality of bits of the detection signal are sequentially corresponding to the plurality of voltage thresholds of the decreasing sequence.

10. The frequency adjustment system of claim 8, wherein when N of the plurality of bits of the detection signal are at the first logic state, the frequency of the system clock signal is the (N+1)^{th} largest of the frequencies of the plurality of clock signals, wherein N is a non-negative integer.

11. The frequency adjustment system of claim 7, wherein the clock selection signal is a digital signal comprising a plurality of bits, and the number of the plurality of bits of the detection signal is different from the number of the plurality of bits of the clock selection signal.

12. The frequency adjustment system of claim 7, wherein the clock providing circuit further comprises a glitch detection circuit configured to prevent a glitch from being generated in the system clock signal.

13. A frequency adjustment method, suitable for a frequency adjustment system and comprising:
detecting, by one or more voltage detection circuits of the frequency adjustment system, a supply voltage of the frequency adjustment system;
comparing, by the one or more voltage detection circuits, the supply voltage with a plurality of voltage thresholds, so as to output a detection signal, wherein the detection signal is a digital signal comprising a plurality of bits respectively related to magnitudes of the supply voltage and the plurality of voltage thresholds;
receiving, by a frequency control circuit of the frequency adjustment system, the detection signal;
generating, by the frequency control circuit, a clock selection signal, based on the detection signal;
receiving, by a clock providing circuit of the frequency adjustment system, the clock selection signal;
selecting, by the clock providing circuit, one of a plurality of clock signals generated by a plurality of clock sources as a system clock signal according to the clock selection signal, wherein frequencies of the plurality of clock signals are different from each other; and
outputting, by the clock providing circuit, the system clock signal to one or more electronic devices of the frequency adjustment system.

14. The frequency adjustment method of claim 13, wherein comparing, by the one or more voltage detection circuits, the supply voltage with the plurality of voltage thresholds, so as to output the detection signal comprises:
in response to the supply voltage being lower than one of the plurality of voltage thresholds, setting a corresponding one of the plurality of bits of the detection signal to a first logic state by the one or more voltage detection circuits; and
in response to the supply voltage being higher than or equal to the one of the plurality of voltage thresholds, setting the corresponding one of the plurality of bits of the detection signal to a second logic state by the one or more voltage detection circuits,
wherein the first logic state is different from the second logic state.

15. The frequency adjustment method of claim 14, wherein the plurality of voltage thresholds form a decreasing sequence, and the plurality of bits of the detection signal are sequentially corresponding to the plurality of voltage thresholds of the decreasing sequence.

16. The frequency adjustment method of claim 14, wherein selecting, by the clock providing circuit, the one of the plurality of clock signals generated by the plurality of clock sources as the system clock signal according to the clock selection signal comprises:
in response to N of the plurality of bits of the detection signal being at the first logic state, selecting one of the plurality of clock signals having the (N+1)^{th} largest of the frequencies of the plurality of clock signals as the system clock signal by the clock providing circuit, wherein N is a non-negative integer.

17. The frequency adjustment method of claim 13, wherein the clock selection signal is a digital signal comprising a plurality of bits, and the number of the plurality of bits of the detection signal is different from the number of the plurality of bits of the clock selection signal.

18. The frequency adjustment method of claim 13, further comprising:
detecting, by a glitch detection circuit of the frequency adjustment system, the system clock signal, so as to prevent a glitch from being generated in the system clock signal.
